(19) United States
(12) Patent Application Publication
(10) Pub. No.: US 2024/0130154 A1
(43) Pub. Date: Apr. 18, 2024

(54) DISPLAY PANEL AND PREPARATION METHOD THEREFOR

(71) Applicant: TCL TECHNOLOGY GROUP CORPORATION, Huizhou, Guangdong (CN)

(72) Inventor: Wenjun HOU, Huizhou, Guangdong (CN)

(21) Appl. No.: 18/263,723

(22) PCT Filed: Dec. 31, 2021
(86) PCT No.: PCT/CN2021/143787

§ 371 Date: Aug. 1, 2023

(30) Foreign Application Priority Data
Apr. 27, 2021 (CN) 202110457431.0

(51) Int. Cl. H10K 50/16; H10K 50/15; H10K 59/35

(52) U.S. Cl. CPC H10K 50/166; H10K 50/156; H10K 59/35; H10K 50/115

(57) ABSTRACT

Embodiments of the present application disclose a display panel and a preparation method therefor, the display panel comprising a first light-emitting unit, a first transparent conductive layer and a second light-emitting unit. The material of the first transparent conductive layer is a n-type semiconductor material; the first transparent conductive layer is disposed on the first light-emitting unit; the second light-emitting unit comprises a first hole injection layer; and the first hole injection layer is disposed on a side of the first transparent conductive layer distant from the first light-emitting unit.

This application claims priority to Chinese Patent Application No. 202110457431.0, filed on Apr. 27, 2021, entitled “DISPLAY PANEL AND PREPARATION METHOD THEREFOR”, which is incorporated herein by reference in its entirety.

### TECHNICAL FIELD

The present application relates to a field of display technology, and more particularly, to a display panel and a preparation method therefor.

### BACKGROUND

When an electroluminescent diode device operates, electrons and holes need to be injected. A quantum dot light-emitting diode device includes a cathode, an electron transport layer, a quantum dot light-emitting layer, a hole transport layer, and an anode. In the quantum dot light-emitting diode device, the quantum dot light-emitting layer is sandwiched between an electron transport layer and a hole transport layer. When a forward bias voltage is applied to both ends of the quantum dot light-emitting diode device, electrons and holes enter the quantum dot light-emitting layer through the electron transport layer and the hole transport layer, respectively, and electrons and holes combine to emit lights in the quantum dot light-emitting layer.

Currently, the quantum dot light-emitting diode device emits lights of a desired color, such as yellow lights, violet lights, or white lights, by mixing at least two of the red quantum dot, green quantum dot, and blue quantum dot in different proportions. However, the quantum dot white light-emitting device prepared as above has a serious disadvantage, for example, electrons and holes required for mixing with the quantum dot light-emitting layer cannot be provided only by the electron transport layer and the hole transport layer, that is, electron concentration and hole concentration generated by the electron transport layer and the hole transport layer are low, so that the quantum dot light-emitting diode device has a poor stability and a affected performance.

### SUMMARY OF THE DISCLOSURE

### Technical Problem

Embodiments of the present application provide a display panel and a preparation method therefor to solve the problems of low concentration in electron and hole in the related art.

### Technical Solutions of the Disclosure

### Summary of the Technical Solutions

An embodiment of the present application provides a display panel including:
a first light-emitting unit;
a first transparent conductive layer, wherein a material of the first transparent conductive layer is a N-type semiconductor material, and the first transparent conductive layer is disposed on the first light-emitting unit; and
a second light-emitting unit, wherein the second light-emitting unit includes a first hole injection layer, and the first hole injection layer is disposed on a side of the first transparent conductive layer away from the first light-emitting unit.

In some embodiments of the present application, the material of the first transparent conductive layer is selected from indium tin oxide, indium zinc oxide, zinc aluminum oxide, indium gallium zinc oxide, zinc oxide, and zinc manganese oxide.

In some embodiments of the present application, the first transparent conductive layer has a thickness ranging from 50 nm to 1000 nm.

In some embodiments of the present application, the first light-emitting unit includes a first electron transport layer, and the first transparent conductive layer is disposed on the first electron transport layer.

In some embodiments of the present application, the second light-emitting unit further includes a second electron transport layer, and the second electron transport layer is disposed on a side of the first hole injection layer away from the first electron transport layer.

In some embodiments of the present application, the display panel further includes a second transparent conductive layer, a material of the second transparent conductive layer is a N-type semiconductor material, and the second transparent conductive layer is disposed on a side of the second electron transport layer away from the first electron transport layer.

In some embodiments of the present application, the material of the second transparent conductive layer is selected from indium tin oxide, indium zinc oxide, zinc aluminum oxide, indium gallium zinc oxide, zinc oxide, and zinc manganese oxide.

In some embodiments of the present application, the second transparent conductive layer has a thickness ranging from 50 nm to 1000 nm.

In some embodiments of the present application, the display panel further includes a third light-emitting unit, and the third light-emitting unit is disposed on a side of the second transparent conductive layer away from the first electron transport layer.

In some embodiments of the present application, the third light-emitting unit includes a second hole injection layer, the second hole injection layer is disposed on a side of the second transparent conductive layer away from the first electron transport layer.

In some embodiments of the present application, the first light-emitting unit, the second light-emitting unit, and the third light-emitting unit are selected from a red light-emitting unit, a green light-emitting unit, and a blue light-emitting unit; wherein the first light-emitting unit, the second light-emitting unit, and the third light-emitting unit emit lights of different colors respectively.

In some embodiments of the present application, the first light-emitting unit further includes an additional hole layer, a first hole transport layer, and a first light-emitting layer arranged sequentially stacked, and the first electron transport layer is disposed on the first light-emitting layer.

In some embodiments of the present application, the second light-emitting unit further includes a second hole transport layer and a second light-emitting layer, the first hole injection layer, the second hole transport layer, the second light-emitting layer, and the second electron transport layer.

In some embodiments of the present application, the third light-emitting unit further includes a third hole transport layer, a third light-emitting layer, and a third electron transport layer sequentially stacked on the second hole injection layer.

In some embodiments of the present application, the display panel further includes a first electrode layer and a second electrode layer, the first electrode layer is disposed on a side of the first light-emitting unit away from the second light-emitting unit, and the second electrode layer is disposed on a side of the third light-emitting unit away from the first light-emitting unit.

In some embodiments of the present application, a material of each of the first light-emitting layer, the second light-emitting layer, and the third light-emitting layer is a core-shell structure; a shell layer the core-shell structurescovers a core layer of the core-shell structure; a material of the core layer includes at least one of CdSe, CdZnSe, InP, and ZnSe; and a material of the shell layer includes one or a combination of CdS and ZnS.

In some embodiments of the present application, materials of the first hole transport layer, the second hole transport layer, and the third hole transport layer include one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, 4,4′-bis(9-carbazol)biphenyl.

In some embodiments of the present application, materials of the first electron transport layer, the second electron transport layer, and the third electron transport layer are selected from ZnO, ZnₓMg_{y}O, Znₘ₁Alₘ₂O, and Znₙ₁Mgₙ₂Liₙ₃O, wherein x+y=1, m1+m2=1, n1+n2+n3=1.

In some embodiments of the present application, materials of the additional hole injection layer, the first hole injection layer, and the second hole injection layer are independently selected from poly(3,4-ethylenedioxythiophene): polystyrene sulfonate, polyaniline, and polythiophene.

Accordingly, the present embodiment further provides a preparation method for a display panel, including:
providing a first light-emitting unit;
forming a first transparent conductive layer on the first light-emitting unit, wherein material of the first transparent conductive layer is a N-type semiconductor material; and
forming a second light-emitting unit on a side of the first transparent conductive layer away from the first light-emitting unit, wherein the second light-emitting unit includes a first hole injection layer, and the first hole injection layer is disposed on the side of the first transparent conductive layer away from the first light-emitting unit.

### Beneficial Effect of the Disclosure

### Beneficial Effect

An embodiment of the present application discloses a display panel and a preparation method for a display panel. The display panel includes a first light-emitting unit, a first transparent conductive layer, and a second light-emitting unit. The first transparent conductive layer is disposed on the first light-emitting unit, a material of the first transparent conductive layer is a N-type semiconductor material. The second light-emitting unit includes a first hole injection layer disposed on a side of the first transparent conductive layer away from the first light-emitting unit. The concentration of electrons and holes required for the display panel increases by providing the first transparent conductive layer between the first light-emitting unit and the second light-emitting unit, thereby improving the display performance of the display panel.

### BRIEF DESCRIPTION OF THE DRAWINGS

### Description of the Drawings

In order to explain the technical solution in the embodiments of the present application more clearly, reference is now made briefly to the accompanying drawings required for the description of the embodiments. It should be understood that the accompanying drawings in the following description are merely some of the embodiments of the present application, and other drawings may be made to a skilled person in the art based on the accompanying drawings without inventive effort.

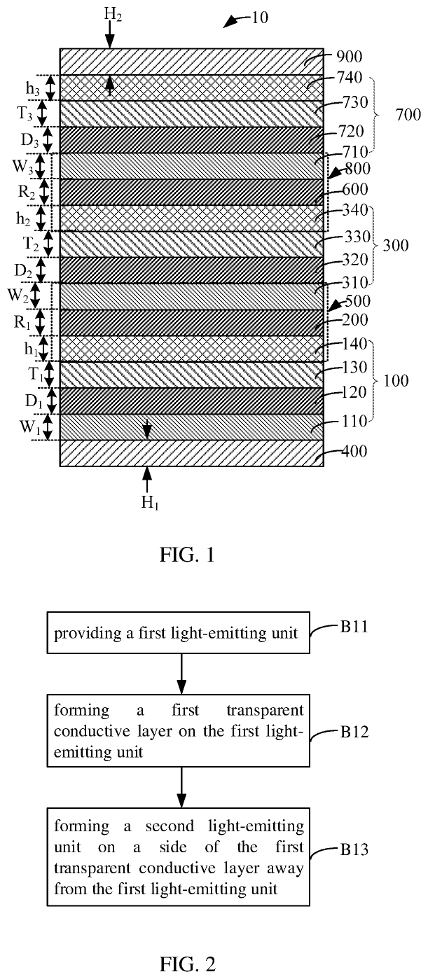

FIG. 1 is a structural schematic diagram of a display panel according to an embodiment of the present application.

FIG. 2 is a flowchart of a preparation method for a display panel according to an embodiment of the present application.

### DETAILED DESCRIPTION OF THE EMBODIMENTS

In the following, the technical solutions in the embodiments of the present application are clearly and completely described in connection with the accompanying drawings in the embodiments of the present application. It should be understood that the described embodiments are merely a part of the embodiments of the present application, rather than all the embodiments. Based on the embodiments in the present application, all other embodiments obtained by a person skilled in the art without inventive effort are within the scope of the present application. Furthermore, it should be understood that the specific embodiments described herein are for purposes of illustration and explanation only, and are not intended to limit the application. In the present application, without stating to the contrary, the positional terms such as “on” and “below” generally refer to a position located on and below the device in actual use and working state, specifically refer to the direction shown in the accompanying drawings. Moreover, the terms “in” and “out” are for the outline of the device.

The embodiment of the application provides a display panel and a preparation method therefor. Detailed descriptions are given below. It should be noted that the order in which the following embodiments are described is not intended to limit the preferred order of the embodiments.

Referring to FIG. 1, FIG. 1 is a structural schematic diagram of a display panel according to an embodiment of the present application. The present application provides a display panel 10. The display panel 10 includes a first light-emitting unit 100, a first transparent conductive layer 200, and a second light-emitting unit 300. The detailed description is as followed.

In an embodiment, the display panel 10 further includes a first electrode layer 400. The first electrode layer 400 may be a cathode or an anode, and in this embodiment, the first electrode layer 400 is an anode.

In an embodiment, the material of the first electrode layer 400 includes one or more of indium tin oxide, indium zinc oxide, zinc aluminum oxide, and indium gallium zinc oxide. In this embodiment, the material of the first electrode layer 400 is indium tin oxide.

In an embodiment, the first electrode layer 400 has a thickness H₁ ranging from 50 nm to 1000 nm. Specifically, the thickness H₁ of the first electrode layer 400 may be 50 nm, 500 nm, 750 nm, 900 nm, 1000 nm, or the like. In this embodiment, H₁ of the first electrode layer 400 is 800 nm.

In the present application, by providing the first electrode layer 400 with the thickness H₁ ranging from 50 nm to 1000 nm, the first electrode layer 400 has a low resistance, and the blocking effect on the current is light, thus, the conductive performance of the first electrode layer 400 is improved. In a case that the thickness H₁ of the first electrode layer 400 is provided less than 50 nm, the first electrode layer 400 has an excessively low resistance, thereby causing damage to the display panel 10. In a case that the thickness H₁ of the first electrode layer 400 is provided greater than 1000 nm, the first electrode layer 400 is excessively high resistance, thereby affecting the conductive performance of the first electrode layer 400 and preventing the display panel 10 from displaying normally.

The first light-emitting unit 100 is disposed on the first electrode layer 400. The first light-emitting unit 100 includes an additional hole injection layer 110, a first hole transport layer 120, a first light-emitting layer 130, and a first electron transport layer 140, which are sequentially stacked on the first electrode layer 400.

In an embodiment, the material of the additional hole injection layer 110 is selected from poly(3,4-ethylenedioxythiophene): polystyrene sulfonate, polyaniline, and polythiophene. In this embodiment, the material of the additional hole injection layer 110 is poly(3,4-ethylenedioxythiophene): polystyrene sulfonate.

In an embodiment, the additional hole injection layer 110 has a thickness W₁ ranging from 15 nm to 50 nm. Specifically, the thickness W₁ of the additional hole injection layer 110 may be 15 nm, 20 nm, 24 nm, 34 nm, 38 nm, 40 nm, 48 nm, 50 nm, or the like. In the present embodiment, the thickness W₁ of the additional hole injection layer 110 is 30 nm.

In the present application, by providing the additional hole injection layer 110 with the thickness W₁ ranging from 15 nm to 50 nm, the injection efficiency of holes in the additional hole injection layer 110 is ensured, the display panel 10 can be normally displayed, and the display performance of the display panel 10 is prevented from being affected.

In an embodiment, the material of the first hole transport layer 120 includes one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl triphenylamine, 4,4′-bis(9-carbazol biphenyl. In this example, the material of the first hole transport layer 120 is 4,4′-bis(9-carbazol biphenyl.

In an embodiment, the first hole transport layer 120 has a thickness D₁ ranging from 15 nm to 40 nm. Specifically, the thickness D₁ of the first hole transport layer 120 may be 15 nm, 20 nm, 24 nm, 34 nm, 38 nm, 40 nm, or the like. In this embodiment, the thickness D₁ of the first hole transport layer 120 is 20 nm.

In the present application, by providing the first hole transport layer 120 with the thickness D₁ ranging from 15 nm to 40 nm, the transport efficiency of holes in the first hole transport layer 120 is ensured, thereby ensuring the normal display of the display panel 10.

In an embodiment, the first light-emitting layer 130 includes one of a red quantum dot light-emitting layer, a green quantum dot light-emitting layer, and a blue quantum dot light-emitting layer. In this embodiment, the first light-emitting layer 130 is the blue quantum dot light-emitting layer, that is, the first light-emitting unit 100 is a blue light-emitting unit.

In an embodiment, the material of the first light-emitting layer 130 is a core-shell structure in which a shell layer covers a core layer. The band gap of the shell layer is greater than the band gap of the core layer.

In the present application, the material of first light-emitting layer 130 is the core-shell structure in which a shell layer covers a core layer, and the band gap of the shell layer is greater than the band gap of the core layer. As such, the first light-emitting layer 130 extends the range of the photon collection spectrum while avoiding the influence of defects of the core layer on the light emission of the first light-emitting layer. Since the material of the first light-emitting layer 130 is the core-shell structure in which the shell layer covers the core layer, the thickness of the shell layer can be adjusted to prevent the coupling characteristics of the core layer from being affected, thereby improving the light-emitting effect of the first light-emitting unit 100 and further improving the stability of the display of the display panel 10.

In an embodiment, the material of the core layer includes at least one of CdSe, CdZnSe, InP, and ZnSe. The material of the shell layer includes one or a combination of CdS and ZnS. In this embodiment, the material of the core layer is ZnSe, and the material of the shell layer is CdS.

In an embodiment, the material of the first light-emitting layer 130 has a particle diameter ranging from 1 nm to 2 nm. In this embodiment, the material of the first light-emitting layer 130 has the particle diameter of 2 nm.

In the present application, the material of the core layer is selected from one of CdSe, CdZnSe, InP and ZnSe, the material of the shell layer is selected from one or a combination of CdS and ZnS, and the material of the first light-emitting layer 130 has the particle diameter of 2 nm, so that the first light-emitting layer 130 emits blue lights.

In an embodiment, the material of the first light-emitting layer 130 has a photoluminescence wavelength ranging from 465 nm to 480 nm.

In an embodiment, the thickness T₁ of the first light-emitting layer 130 ranges from 10 nm to 40 nm. Specifically, the thickness T₁ of the first light-emitting layer 130 may be 10 nm, 12 nm, 15 nm, 20 nm, 24 nm, 34 nm, 38 nm, 40 nm, or the like. In this embodiment, the thickness T₁ of the first light-emitting layer 130 is 20 nm.

In the present application, the thickness T₁ of the first light-emitting layer 130 ranges from 10 nm to 40 nm, so that the first light-emitting layer 130 can emit lights normally, and the display panel 10 can be displayed normally.

In an embodiment, the material of the first electron transport layer 140 is selected from ZnO, ZnₓMg_{y}O, Znₘ₁Alₘ₂O, and Znₙ₁Mgₙ₂Liₙ₃O, where x+y=1, m1+m2=1, n1+n2+n3=1. In this embodiment, the material of the first electron transport layer 140 is Zn_{0.95}Mg_{0.05}O.

In an embodiment, the first electron transport layer 140 has a thickness h₁ ranging from 20 nm to 60 nm. Specifically, the thickness h₁ of the first electron transport layer 140 may be 20 nm, 24 nm, 34 nm, 38 nm, 40 nm, 50 nm, 54 nm, 60 nm, or the like. In the present embodiment, the thickness h₁ of the first electron transport layer 140 is 30 nm.

In the present application, by providing the first electron transport layer 140 with the thickness h₁ ranging from 20 nm to 60 nm, thereby ensuring electron transport performance of the first electron transport layer 140 and further ensuring the normal display of the display panel 10.

The first transparent conductive layer 200 is disposed on a side of the first electron transport layer 140 away from the additional hole injection layer 110.

In an embodiment, the material of the first transparent conductive layer 200 is selected from indium tin oxide, indium zinc oxide, zinc aluminum oxide, indium gallium zinc oxide, zinc oxide, and zinc manganese oxide. In the present embodiment, the material of the first transparent conductive layer 200 is indium zinc oxide.

In an embodiment, the first transparent conductive layer 200 has a thickness R₁ ranging from 50 nm to 1000 nm. Specifically, the thickness R₁ of the first transparent conductive layer 200 may be 50 nm, 500 nm, 750 nm, 900 nm, 1000 nm, or the like. In this embodiment, the thickness R₁ of the first transparent conductive layer 200 is 100 nm.

In the present application, the first transparent conductive layer 200 is provided with the thickness R₁ ranging from 50 nm to 1000 nm, to avoid the influence of the first hole injection layer 310 on the first electron transport layer 140 subsequently, thereby ensuring the injection of the first electron transport layer 140 and the transmission of electrons, and ensuring the normal display of the display panel 10. In a case that the thickness R₁ of the first transparent conductive layer 200 is less than 50 nm, the first hole injection layer 310 affects electron injection and transmission efficiency of the first electron transport layer 140, so that the display panel 10 cannot be normally displayed. In a case that the thickness R₁ of the first transparent conductive layer 200 is 1000 nm, the resistance of the first transparent conductive layer 200 is increased, so that the conductivity of the first transparent conductive layer 200 is reduced, thereby affecting the display performance of the display panel 10.

The second light-emitting unit 300 includes a first hole injection layer 310, a second hole transport layer 320, a second light-emitting layer 330, and a second electron transport layer 340, which are sequentially stacked on the first transparent conductive layer 200.

In an embodiment, the material of the first hole injection layer 310 is selected from poly(3,4-ethylenedioxythiophene): polystyrene sulfonate, polyaniline, and polythiophene. In this embodiment, the material of the first hole injection layer 310 is poly(3,4-ethylenedioxythiophene): polystyrene sulfonate.

In an embodiment, the first hole injection layer 310 has a thickness W₂ ranging from 15 nm to 50 nm. Specifically, the thickness W₂ of the first hole injection layer 310 may be 15 nm, 20 nm, 24 nm, 34 nm, 38 nm, 40 nm, 48 nm, 50 nm, or the like. In this embodiment, the thickness W₂ of the first hole injection layer 310 is 30 nm.

In the present application, by providing the first hole injection layer 310 with the thickness W₂ ranging from 15 nm to 50 nm, the injection efficiency of holes in the first hole injection layer 310 is ensured, thereby ensuring normal display of the display panel 10.

The first electron transport layer 140, the first transparent conductive layer 200, and the first hole injection layer 310 define a first charge layer 500 of the display panel 10. The first charge layer 500 is configured to generate a charge.

In the present application, the first charge layer 500 is defined by the first electron transport layer 140, the first transparent conductive layer 200, and the first hole injection layer 310. Because the first transparent conductive layer 200 is in form of a N-type semiconductor, and the first hole injection layer 310 is in form of a P-type semiconductor, the first transparent conductive layer 200 and the first hole injection layer 310 define a P-N junction. With the conduction band of the first transparent conductive layer 200 equal to or less than the highest occupied molecular orbital (HOMO) of the first hole injection layer 310, when an external electric field is applied, electrons and holes are generated at the P-N junction, electrons are injected into the light-emitting unit through the first transparent conductive layer 200, holes are injected into another light-emitting unit, and the first electron transport layer 140 is configured to transport electrons to the first light-emitting layer 130. That is, the first charge layer 500 can generate enough electrons and holes, thereby avoiding the problem of energy transfer caused by the stacked arrangement of the light-emitting units of the display panel 10. In turn, the stability of the display panel 10 is improved.

In an embodiment, the material of the second hole transport layer 320 is selected from one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, 4,4′-bis(9-carbazol)biphenyl. In this embodiment, the material of the second hole transport layer 320 is polyvinylcarbazole.

In an embodiment, the second hole transport layer 320 has a thickness D₂ ranging from 15 nm to 40 nm. Specifically, the thickness D₂ of the first hole transport layer 120 may be 15 nm, 20 nm, 24 nm, 34 nm, 38 nm, 40 nm, or the like. In this embodiment, the thickness D₂ of the second hole transport layer 320 is 25 nm.

In the present application, by providing the second hole transport layer 320 with the thickness D₂ ranging from 15 nm to 40 nm, the transport efficiency of holes in the second hole transport layer 320 is ensured, thereby ensuring the normal display of the display panel 10.

In an embodiment, the second light-emitting layer 330 includes one of a red quantum dot light-emitting layer, a green quantum dot light-emitting layer, and a blue quantum dot light-emitting layer. In this embodiment, the second light-emitting layer 330 is the green quantum dot light-emitting layer, that is, the second light-emitting unit 300 is the green light-emitting unit.

In an embodiment, the material of the second light-emitting layer 330 is a core-shell structure in which a shell layer covers a core layer. The material of the core layer includes one of CdSe, CdZnSe, InP, and ZnSe. The material of the shell layer includes one or a combination of CdS and ZnS. In this embodiment, the material of the core layer is CdZnSe, and the material of the shell layer is CdS.

In an embodiment, the material of the second light-emitting layer 330 has a particle diameter ranging from 3 nm to 6 nm. In this embodiment, the material of the second light-emitting layer 330 has the particle diameter of 5 nm.

In the present application, the material of the core layer includes CdSe, CdZnSe, InP, and ZnSe, the material of the shell layer includes CdS and ZnS, and the particle diameter of the material of the second light-emitting layer 330 ranges from 3 nm to 6 nm. As such, the second light-emitting layer 330 emits green lights.

In an embodiment, the material of the second light-emitting layer 330 has a photoluminescence wavelength ranging from 535 nm to 555 nm.

In an embodiment, the thickness T₂ of the second light-emitting layer 330 ranges from 10 nm to 40 nm. Specifically, the thickness T₂ of the second light-emitting layer 330 may be 10 nm, 12 nm, 15 nm, 20 nm, 24 nm, 34 nm, 38 nm, 40 nm, or the like. In this embodiment, the thickness T₂ of the second light-emitting layer 330 is 15 nm.

In the present application, by providing the second light-emitting layer 330 with the thickness T₂ ranging from 10 nm to 40 nm, the second light-emitting layer 330 can emit lights normally, and the display panel 10 can be displayed normally.

In an embodiment, the material of the second electron transport layer 340 is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1. In this embodiment, the material of the second electron transport layer 340 is Zn_{0.95}Mg_{0.05}O.

In an embodiment, the second electron transport layer 340 has a thickness h₂ ranging from 20 nm to 60 nm. Specifically, the thickness h₂ of the second electron transport layer 340 may be 20 nm, 24 nm, 34 nm, 38 nm, 40 nm, 50 nm, 54 nm, 60 nm, or the like. In this embodiment, the thickness h₂ of the second electron transport layer 340 is 38 nm.

In the present application, by providing the second electron transport layer 340 with the thickness h₂ ranging from 20 nm to 60 nm, to ensure electron transport of the second electron transport layer 340 is ensured, thereby ensuring the normal display of the display panel 10.

In an embodiment, the display panel 10 further includes a second transparent conductive layer 600. The second transparent conductive layer 600 is disposed on a side of the second electron transport layer 340 away from the first electrode layer 400.

In an embodiment, the material of the second transparent conductive layer 600 is selected from indium tin oxide, indium zinc oxide, zinc aluminum oxide, indium gallium zinc oxide, zinc oxide, and zinc manganese oxide. In this embodiment, the material of the second transparent conductive layer 600 is indium zinc oxide.

In an embodiment, the thickness R₂ of the second transparent conductive layer 600 has a thickness R₂ ranging from 50 nm to 1000 nm. Specifically, the thickness R₂ of the second transparent conductive layer 600 may be 50 nm, 500 nm, 750 nm, 900 nm, 1000 nm, or the like. The thickness R₂ of the second transparent conductive layer 600 is 500 nm.

In the present application, by providing the second transparent conductive layer 600 with the thickness R₂ ranging from 50 nm to 1000 nm, the influence of the second hole injection layer 710 on the second electron transport layer 340 is subsequently avoided, electron injection and transmission efficiency of the second electron transport layer 340 are ensured, and the normal display of the display panel 10 is ensured. In a case that the thickness R₂ of the second transparent conductive layer 600 is provided less than 50 nm, the second hole injection layer 710 affects electron injection and transmission efficiency of the second electron transport layer 340, so that the display panel 10 cannot be normally displayed. In a case that the thickness R₂ of the second transparent conductive layer 600 is provided as 1000 nm, the resistance of the second transparent conductive layer 600 is increased, so that the conductivity of the second transparent conductive layer 600 is reduced, thereby affecting the display performance of the display panel 10.

The display panel 10 further includes a third light-emitting unit 700. The third light-emitting unit 700 is disposed on the second transparent conductive layer 600. The third light-emitting unit 700 includes a second hole injection layer 710, a third hole transport layer 720, a third light-emitting layer 730, and a third electron transport layer 740, which are sequentially stacked on the second transparent conductive layer 600.

In an embodiment, the material of the additional hole injection layer 110 is selected from poly(3,4-ethylenedioxythiophene): polystyrene sulfonate, polyaniline, and polythiophene. In this embodiment, the material of the second hole injection layer 710 is poly(3,4-ethylenedioxythiophene): polythiophene.

In an embodiment, the second hole injection layer 710 has a thickness W₃ ranging from 15 nm to 50 nm. Specifically, the thickness W₃ of the second hole injection layer 710 may be 15 nm, 20 nm, 24 nm, 34 nm, 38 nm, 40 nm, 48 nm, 50 nm, or the like. In this embodiment, the thickness W₃ of the second hole injection layer 710 is 39 nm.

In the present application, by providing the second hole injection layer 710 with the thickness W₃ ranging from 15 nm to 50 nm, the injection efficiency of holes in the second hole injection layer 710 is ensured, and the normally display of the display panel 10 is ensured.

In the present application, the second transparent conductive layer 600 is disposed between the second electron transport layer 340 and the second hole injection layer 710. Since the second transparent conductive layer 600 is in form of a N-type semiconductor and the second hole injection layer 710 is in form of a P-type semiconductor, the second transparent conductive layer 600 and the second hole injection layer 710 define a P-N junction. With the conduction band of the first transparent conductive layer 200 equal to or less than the highest occupied molecular orbital (HOMO) of the second hole injection layer 710, when an applied electric field is applied, electrons and holes are generated at the P-N junction, electrons are injected into the light-emitting unit through the second transparent conductive layer 600, holes are injected into another light-emitting unit, and the second electron transport layer 340 is configured to transport electrons to the second light-emitting layer 330. That is, the second charge layer 800 defined by the second electron transport layer 340, the second hole injection layer 710, and the second transparent conductive layer 600 can generate enough electrons and holes. Further, the problem of energy transfer caused by the stacked arrangement of the light-emitting units of the display panel 10 is avoided, and the stability of the display of the display panel 10 is improved.

In an embodiment, the material of the third hole transport layer 720 includes one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, 4,4′-bis(9-carbazol)biphenyl. In this embodiment, the material of the third hole transport layer 720 is poly(N,N′-bis(4-butylphenyl)-N,N′-bis(phenyl)-benzidine).

In an embodiment, the third hole transport layer 720 has a thickness D₃ ranging from 15 nm to 40 nm. Specifically, the thickness D₃ of the third hole transport layer 720 may be 15 nm, 20 nm, 24 nm, 34 nm, 38 nm, 40 nm, or the like. In this embodiment, the thickness D₃ of the third hole transport layer 720 is 18 nm.

In the present application, by providing the third hole transport layer 720 with the thickness D₃ ranging from 15 nm to 40 nm, the transport efficiency of holes in the third hole transport layer 720 is ensured, thereby ensuring the normal display of the display panel 10.

In an embodiment, the third light-emitting layer 730 includes one of a red quantum dot light-emitting layer, a green quantum dot light-emitting layer, and a blue quantum dot light-emitting layer. In this embodiment, the third light-emitting layer 730 is the red quantum dot light-emitting layer, that is, the third light-emitting unit 700 is the red light-emitting unit.

In an embodiment, the material of the third light-emitting layer 730 is a core-shell structure in which a shell layer covers a core layer. The material of the core layer includes one of CdSe, CdZnSe, InP, and ZnSe. The material of the shell layer includes one or a combination of CdS and ZnS. In this embodiment, the material of the core layer is ZnSe, and the material of the shell layer is a combination of CdS and ZnS.

In an embodiment, the third light-emitting layer 730 material has a particle diameter ranging from 7 nm to 8 nm. In this embodiment, the material of the third light-emitting layer 730 has the particle diameter of 8 nm.

In the present application, the material of the core layer includes CdSe, CdZnSe, InP, and ZnSe, the material of the shell layer includes CdS and ZnS, and the particle diameter of the material of the third light-emitting layer 730 ranges from 7 nm to 8 nm. As such, the third light-emitting layer 730 emits red lights.

In an embodiment, the material of the third light-emitting layer 730 has a photoluminescence wavelength ranging from 615 nm to 625 nm.

In an embodiment, the third light-emitting layer 730 has a thickness T₃ ranging from 10 nm to 40 nm. Specifically, the thickness T₃ of the third light-emitting layer 730 may be 10 nm, 12 nm, 15 nm, 20 nm, 24 nm, 34 nm, 38 nm, 40 nm, or the like. In this embodiment, the thickness T₃ of the third light-emitting layer 730 is 22 nm.

In the present application, by providing the third light-emitting layer 730 with the thickness T₃ ranging from 10 nm to 40 nm, the third light-emitting layer 730 can emit lights normally, and the display panel 10 can be displayed normally.

In an embodiment, the material of the third electron transport layer 740 is selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1. In this embodiment, the material of the third electron transport layer 740 is Zn_{0.85}Mg_{0.05}Li_{0.1}O.

In an embodiment, the third electron transport layer 740 has a thickness h₃ ranging from 20 nm to 60 nm. Specifically, the thickness h₃ of the third electron transport layer 740 may be 20 nm, 24 nm, 34 nm, 38 nm, 40 nm, 50 nm, 54 nm, 60 nm, or the like. In this embodiment, the thickness h₃ of the third electron transport layer 740 is 54 nm.

In an embodiment, the display panel 10 further includes a second electrode layer 900. The second electrode layer 900 is disposed on a side of the third electron transport layer 740 away from the first electrode layer 400.

In an embodiment, the material of the second electrode layer 900 includes gold, silver, aluminum, alloys thereof, and the like. In this embodiment, the material of the second electrode layer 900 is gold.

In an embodiment, the second electrode layer 900 has a thickness H₂ ranging from 80 nm to 500 nm. Specifically, the thickness H₂ of the second electrode layer 900 may be 80 nm, 120 nm, 340 nm, 480 nm, 500 nm, or the like. In an embodiment, the thickness H₂ of the second electrode layer 900 is 100 nm. In this embodiment, the thickness H₂ of the second electrode layer 900 is 490 nm.

In the present application, by providing the second electrode layer 900 with the thickness H₂ ranging from 80 nm to 500 nm, the resistance of the second electrode layer 900 is low, and the blocking effect on the current is light, thereby improving the conductivity of the second electrode layer 900 and reducing the light transmittance of the second electrode layer 900. In a case that the thickness H₂ of the second electrode layer 900 is provided less than 80 nm, lights are easily transmitted by the second electrode layer 900, thereby affecting the display effect of the display panel 10. In a case that the thickness H₂ of the second electrode layer 900 is provided greater than 500 nm, the second electrode layer 900 is excessively thick and the resistance of the second electrode layer 900 is excessively high, thereby affecting the conductivity of the second electrode layer 900 and preventing the display panel 10 from displaying normally. In addition, the material of the second electrode layer 900 is a metal, which has a high cost, as such, the second electrode layer 900 with the thickness H₂ greater than 500 nm may further increase the cost.

The present application provides a display panel in which a transparent conductive layer is introduced between stacked light-emitting units. As such, A P-N junction is defined between the transparent conductive layer and the hole injection layer of the light-emitting unit, thereby increasing the concentration of electrons and holes, and avoiding energy transfer among the stacked light-emitting units. Thus, the display stability of the display panel 10 is improved, and the display performance of the display panel 10 is improved.

Referring to FIG. 2, FIG. 2 is a flowchart of a preparation method for a display panel according to an embodiment of the present application. The present application also provides a preparation method for a display panel, which is specifically described as follows.

In step B11, a first light-emitting unit is provided.

In an embodiment, before the step B11, the preparation method further includes:

forming a first electrode layer 400 by sputtering a material of the first electrode layer 400 through a sputtering process.

In an embodiment, the material of the first electrode layer 400 includes one or more of indium tin oxide, indium zinc oxide, zinc aluminum oxide, and indium gallium zinc oxide. In this embodiment, the material of the first electrode layer 400 is indium tin oxide.

In an embodiment, after the step of forming the first electrode layer 400, the preparation method further includes:

forming an additional hole injection layer 110 on the first electrode 140 by disposing a material of the additional hole injection layer 110 on the first electrode 140 through spin coating, ink jet printing, or slit coating.

In an embodiment, the material of the additional hole injection layer 110 is selected from poly(3,4-ethylenedioxythiophene): polystyrene sulfonate, polyaniline, and polythiophene. In this embodiment, the material of the additional hole injection layer 110 is poly(3,4-ethylenedioxythiophene): polystyrene sulfonate.

In an embodiment, after the step of forming the additional hole injection layer 110 on the first electrode layer 400, the preparation method further includes:
forming a first hole transport layer 120 on a side of the additional hole injection layer 110 away from the first electrode layer 400 by disposing a material of the first hole transport layer 120 on the side of the additional hole injection layer 110 away from the first electrode layer 400 through spin coating, ink jet printing, or slit coating; and
forming a first light-emitting layer 130 on a side of the first hole transport layer 120 away from the first electrode layer 400 by disposing a material of the first light-emitting layer 130 on the side of the first hole transport layer 120 away from the first electrode layer 400 through spin coating, ink jet printing, or slit coating.

In an embodiment, the material of the first light-emitting layer 130 is a core-shell structure in which a shell layer covers a core layer. The band gap of the shell layer is greater than the band gap of the core layer.

In the present application, the material of the first light-emitting layer 130 is the core-shell structure in which the shell layer covers the core layer, and the band gap of the shell layer is greater than the band gap of the core layer, so that the first light-emitting layer 130 expands the range of the photon collection spectrum while avoiding the influence of defects of the core layer on the light emission of the first light-emitting unit 100. In addition, by adjusting the thickness of the shell layer, the coupling characteristics of the core layer can be prevented from being affected, thereby improving the stability of the display of the display panel 10.

In an embodiment, the material of the core layer includes one of CdSe, CdZnSe, InP, and ZnSe. The material of the shell layer includes one or a combination of CdS and ZnS. In this embodiment, the material of the core layer is ZnSe, and the material of the shell layer is CdS.

In an embodiment, after the step of forming the first light-emitting layer 130 on the side of the first hole transport layer 120 away from the first electrode layer 400, the preparation method further includes:

forming a first electron transport layer 140 on a side of the first light-emitting layer 130 away from the electrode layer 400 by sputtering a material of the first electron transport layer 140 on the side of the first light-emitting layer 130 away from the electrode layer 400 through a sputtering process.

The additional hole injection layer 110, the first hole transport layer 120, the first light-emitting layer 130, and the first electron transport layer 140 define the first light-emitting unit 100 of the display panel 10.

In step B12, a first transparent conductive layer is formed on the first light-emitting unit.

The first transparent conductive layer 200 is formed by sputtering a material of the first transparent conductive layer 200 on a side of the first electron transport layer 140 away from the first electrode layer 400 through a sputtering process.

In step B13, a second light-emitting unit is formed on a side of the first transparent conductive layer away from the first light-emitting unit.

In an embodiment, before the step B13, the preparation method further includes:

forming a first hole injection layer 310 on a side of the first transparent conductive layer 200 away from the first electrode layer 400 by sputtering a material of the first hole injection layer 310 on the side of the first transparent conductive layer 200 away from the first electrode layer 400 through a sputtering process.

In the present application, the first electron transport layer 140, the first transparent conductive layer 200, and the first hole injection layer 310 are formed by the sputtering processes to define as a first charge layer 500 in the stacked light-emitting units, so that electrons and holes as required can be efficiently supplied, and the problem of mutual dissolution between the film layers can be avoided, thereby improving the stability of the display panel.

In an embodiment, after the step B12, the preparation method further includes:

forming a second hole transport layer 320 on a side of the first hole injection layer 310 away from the first electrode layer 400 by disposing a material of the second hole transport layer 320 on the side of the first hole injection layer 310 away from the first electrode layer 400 through spin coating, ink jet printing, or slit coating.

In an embodiment, after the step of forming the second hole transport layer 320 on the side of the first hole injection layer 310 away from the first electrode layer 400, the preparation method further includes:

forming a second light-emitting layer 330 on a side of the second hole transport layer 320 away from the first electrode layer 400 by disposing a material of the second light-emitting layer 330 on the side of the second hole transport layer 320 away from the first electrode layer 400 through spin coating, ink jet printing, or slit coating.

In an embodiment, after the step of forming the second light-emitting layer 330 on the side of the second hole transport layer 320 away from the first electrode layer 400, the preparation method further includes:

forming a second electron transport layer 340 on a side of the second light-emitting layer 330 away from the first electrode layer 400 by sputtering a material of the second electron transport layer 340 on the side of the second light-emitting layer 330 away from the first electrode layer 400 through a sputtering process.

The first hole injection layer 310, the second hole transport layer 320, the second light-emitting layer 330, and the second electron transport layer 340 define the second light-emitting unit 300 of the display panel 10.

In an embodiment, after the step of forming the second electron transport layer 340 on the side of the second light-emitting layer 330 away from the first electrode layer 400, the preparation method further includes:
forming a second transparent conductive layer 600 on a side of the second electron transport layer 340 away from the first electrode layer 400 by sputtering a material of the second transparent conductive layer 600 on the side of the second electron transport layer 340 away from the first electrode layer 400; and
forming a second hole injection layer 710 on a side of the second transparent conductive layer 600 away from the first electrode layer 400 by sputtering a material of the second hole injection layer 710 on the side of the second transparent conductive layer 600 away from the first electrode layer 400 through a sputtering process.

In the present application, the second electron transport layer 340, the second transparent conductive layer 600, and the second hole injection layer 710 are formed by the sputtering processes and define a second charge layer 800 in the stacked light-emitting units, so that electrons and holes as required can be efficiently supplied by the second charge layer 800, while avoiding the problem of mutual dissolution between the film layers, thereby improving the stability of the device.

In an embodiment, after the step of forming the second hole injection layer 710 on the side of the second transparent conductive layer 600 away from the first electrode layer 400, the preparation method further includes:
forming a third hole transport layer 720 on a side of the second hole injection layer 710 away from the first electrode layer 400 by disposing a material of the third hole transport layer 720 on the side of the second hole injection layer 710 away from the first electrode layer 400 through spin coating, ink jet printing, or slit coating; and
forming a third light-emitting layer 730 on a side of the third hole transport layer 720 away from the first electrode layer 400 by disposing a material of the third light-emitting layer 730 on the side of the third hole transport layer 720 away from the first electrode layer 400 through spin coating, ink jet printing, or slit coating.

In an embodiment, after the step of forming the third light-emitting unit on the side of the third hole transport layer 720 away from the first electrode layer 400, the preparation method further includes:
forming a third electron transport layer 740 on a side of the third light-emitting layer 730 away from the electrode layer 400 by sputtering a material of the third electron transport layer 740 on the side of the third light-emitting layer 730 away from the electrode layer 400 through a sputtering process.

In an embodiment, after the step of forming the third electron transport layer 740 on the side of the third light-emitting layer 730 away from the first electrode layer 400, the preparation method further includes:
forming a second electrode layer 900 on a side of the third electron transport layer 740 away from the first electrode layer 400 by evaporating or sputtering a material of the second electrode layer 900 on the side of the third electron transport layer 740 away from the first electrode layer 400 through an evaporation or sputtering process.

The present application provides the preparation method for the display panel, in which the first electron transport layer 140, the first transparent conductive layer 200, and the first hole injection layer 310 of the first charge layer 500 are formed by the sputtering processes, so that the first charge layer 500 can efficiently supply required electrons and holes while avoiding a problem of mutual dissolution between film layers, thereby improving stability of the display panel, and reducing costs.

An embodiment of the present application discloses a display panel, and a preparation method for a display panel. The display panel includes a first light-emitting unit, a first transparent conductive layer, and a second light-emitting unit. The first transparent conductive layer is disposed on the first light-emitting unit, and the second light-emitting unit is disposed on a side of the first transparent conductive layer away from the first light-emitting unit. The concentration of electrons and holes required for the display panel increases by providing the first transparent conductive layer between the first light-emitting unit and the second light-emitting unit, thereby improving the display performance of the display panel.

A display panel and a preparation method for the same provided by the present application are described in details, and the principles and embodiments of the present application are described with reference to specific examples. The description of the above examples is merely provided to help understand the method and the core idea of the present application. At the same time, variations to the detailed embodiments and the scope of application will occur to those skilled in the art in accordance with the teachings of the present application. In view of the foregoing, the present description should not be construed as limiting the application.

1. A display panel, comprising:
a first light-emitting unit;
a first transparent conductive layer, wherein a material of the first transparent conductive layer is a N-type semiconductor material, and the first transparent conductive layer is disposed on the first light-emitting unit; and
a second light-emitting unit, wherein the second light-emitting unit comprises a first hole injection layer, and the first hole injection layer is disposed on a side of the first transparent conductive layer away from the first light-emitting unit.

2. The display panel of claim 1, wherein the material of the first transparent conductive layer is selected from indium tin oxide, indium zinc oxide, zinc aluminum oxide, indium gallium zinc oxide, zinc oxide, and zinc manganese oxide.

3. The display panel of claim 1, wherein the first transparent conductive layer has a thickness ranging from 50 nm to 1000 nm.

4. The display panel of claim 1, wherein the first light-emitting unit comprises a first electron transport layer, and the first transparent conductive layer is disposed on the first electron transport layer.

5. The display panel of claim 4, wherein the second light-emitting unit further comprises a second electron transport layer, and the second electron transport layer is disposed on a side of the first hole injection layer away from the first electron transport layer.

6. The display panel of claim 5, wherein the display panel further comprises a second transparent conductive layer, a material of the second transparent conductive layer is a N-type semiconductor material, and the second transparent conductive layer is disposed on a side of the second electron transport layer away from the first electron transport layer.

7. The display panel of claim 6, wherein the material of the second transparent conductive layer is selected from indium tin oxide, indium zinc oxide, zinc aluminum oxide, indium gallium zinc oxide, zinc oxide, and zinc manganese oxide.

8. The display panel of claim 6, wherein the second transparent conductive layer has a thickness ranging from 50 nm to 1000 nm.

9. The display panel of claim 6, wherein the display panel further comprises a third light-emitting unit, and the third light-emitting unit is disposed on a side of the second transparent conductive layer away from the first electron transport layer.

10. The display panel of claim 9, wherein the third light-emitting unit comprises a second hole injection layer, the second hole injection layer is disposed on a side of the second transparent conductive layer away from the first electron transport layer.

11. The display panel of claim 10, wherein the first light-emitting unit, the second light-emitting unit, and the third light-emitting unit are selected from a red light-emitting unit, a green light-emitting unit, and a blue light-emitting unit; wherein the first light-emitting unit, the second light-emitting unit, and the third light-emitting unit emit lights of different colors respectively.

12. The display panel of claim 4, wherein the first light-emitting unit further comprises an additional hole layer, a first hole transport layer, and a first light-emitting layer arranged sequentially stacked, and the first electron transport layer is disposed on the first light-emitting layer.

13. The display panel of claim 5, wherein the second light-emitting unit further comprises a second hole transport layer and a second light-emitting layer; the first hole injection layer, the second hole transport layer, the second light-emitting layer, and the second electron transport layer are sequentially stacked on the first transparent conductive layer.

14. The display panel of claim 10, wherein the third light-emitting unit further comprises a third hole transport layer, a third light-emitting layer, and a third electron transport layer sequentially stacked on the second hole injection layer.

15. The display panel of claim 14, wherein the display panel further comprises a first electrode layer and a second electrode layer, the first electrode layer is disposed on a side of the first light-emitting unit away from the second light-emitting unit, and the second electrode layer is disposed on a side of the third light-emitting unit away from the first light-emitting unit.

16. The display panel of claim 14, wherein a material of each of the first light-emitting layer, the second light-emitting layer, and the third light-emitting layer has a core-shell structure; a shell layer of the core-shell structure covers a core layer of the core-shell structure; a material of the core layer comprises at least one of CdSe, CdZnSe, InP, and ZnSe; and a material of the shell layer includes one or a combination of CdS and ZnS.

17. The display panel of claim 14, wherein materials of the first hole transport layer, the second hole transport layer, and the third hole transport layer comprise one or more of poly(9,9-dioctylfluorene-co-N-(4-butylphenyl)diphenylamine), poly(N,N′-bis(4-butylphenyl)-N,N′-bis(phenyl)-benzidine), polyvinylcarbazole, 4,4′,4″-tris(carbazol-9-yl)triphenylamine, 4,4′-bis(9-carbazol)biphenyl.

18. The display panel of claim 14, wherein materials of the first electron transport layer, the second electron transport layer, and the third electron transport layer are selected from ZnO, ZnₓMg_{y}O, Znₘ₁Alₘ₂O, and Znₙ₁Mgₙ₂Liₙ₃O, wherein x, y, m1, m2, n1, n2, and n3 are satisfied with: x+y=1, m1+m2=1, n1+n2+n3=1.

19. The display panel of claim 14, wherein materials of the additional hole injection layer, the first hole injection layer, and the second hole injection layer are independently selected from poly(3,4-ethylenedioxythiophene): polystyrene sulfonate, polyaniline, and polythiophene.

20. A preparation method for a display panel, comprising:
providing a first light-emitting unit;
forming a first transparent conductive layer on the first light-emitting unit, wherein material of the first transparent conductive layer is a N-type semiconductor material; and
forming a second light-emitting unit on a side of the first transparent conductive layer away from the first light-emitting unit, wherein the second light-emitting unit comprises a first hole injection layer, and the first hole injection layer is disposed on the side of the first transparent conductive layer away from the first light-emitting unit.
